(19) United States
(12) Patent Application Publication
(10) Pub. No.: US 2006/0285419 A1
(43) Pub. Date: Dec. 21, 2006

(54) Flexible capacity memory IC

(76) Inventors: Chi-Cheng Hung, Hsinchu City (TW); Ling-Yueh Chang, Hsinchu (TW); Pwu-Yueh Chung, Taoyuan (TW)

Correspondence Address: HungChang Lin, 8 Schindler Ct., Silver Spring, MD, 20903, US

(21) Appl. No.: 11/153,264

(22) Filed: Jun. 16, 2005

(51) Int. Cl. G11C 8/00

(52) U.S. Cl. 365/230.03

(57) ABSTRACT

More than one memory areas are connected in parallel to increase the memory capacity when activated. The different memory area in a single unit die is activated by a selector pad which controls a single-pole, double throw switch to enable or disable the different memory areas. The corresponding pads of like memory areas are interconnected.

### BACKGROUND OF THE INVENTION

1. Field of the Invention

This invention relates to integrated circuit (IC) memory, particularly to expandable IC memory on the same chip.

2. Brief Description of Related Art

FIG. 1 shows two adjacent IC memory areas 10 on a common wafer. Each memory area 10 has numerous pads 12 that can be signal pads, power pads, or other functional pads. These pads 12 are used to couple to external circuits. When a customer requests a single capacity memory chip, the wafer is sawed along the horizontal lines H1 and vertical lines V1 to yield single dice each with single capacity memory. When the customer requests double capacity memory, it is necessary that a new product different from the single capacity memory die 10 be redesigned to meet the requirements of double capacity memory. In traditional practice, the double capacity cannot be obtained from combining two of the single capacity memory areas at wafer stage.

### SUMMARY OF THE INVENTION

An object of the present invention is to provide means to expand memory capacity without requiring much change in IC design and manufacturing process. Another object of this invention is to make the same IC layout flexible to accommodate different memory capacity.

This invention disclosed a method and product that combines two neighboring single capacity memory area into a double capacity memory unit in wafer stage through additional two mask layers process. In so doing, the production cost is greatly decreased. This invention provides a single process design to yield two or more different capacity memory ICs processed with or without using additional mask layers.

These objects are achieved by adding at least one “selector pad” on each basic memory area unit. The selector pad controls a single-pole, double-throw switch (not shown), which enables or disables the chip on which the selector pad is placed. With the control of the selector pad, the wafer can be sawed to yield appropriate memory capacity dice. e.g. to cut apart single memory area on a wafer provides single capacity memory ICs; to cut double memory areas on the same wafer provides double capacity memory ICs . . . etc. One of the embodiments is to show a single design process with or without using additional two mask layers in the last few steps can meet the choices from two memory capacity products—single capacity memory ICs or double capacity memory ICs.

### BRIEF DESCRIPTION OF THE DRAWINGS

FIG. 1 shows a prior art layout of two adjacent memory areas on a wafer.

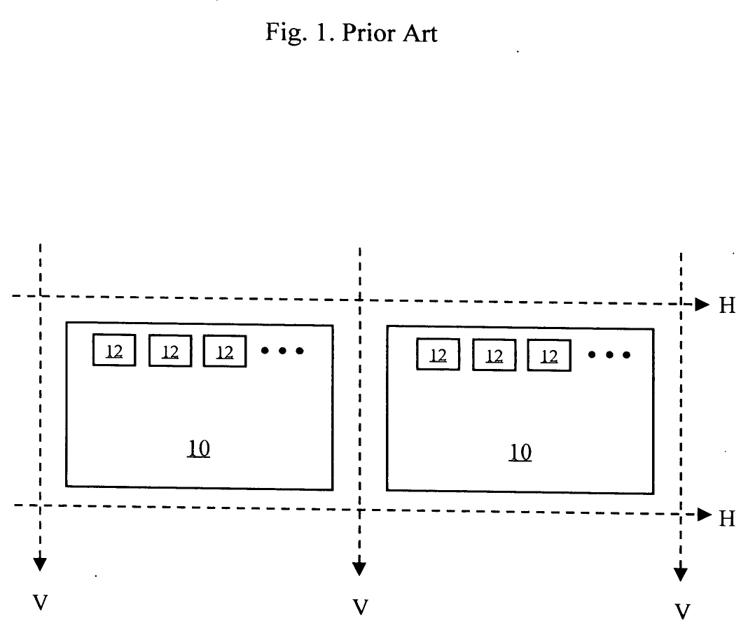

FIG. 2 shows the basic layout of the present invention with the addition of a selector pad.

FIG. 3 show the interconnection of corresponding signal pads for doubling the memory capacity.

### DETAILED DESCRIPTION OF THE INVENTION

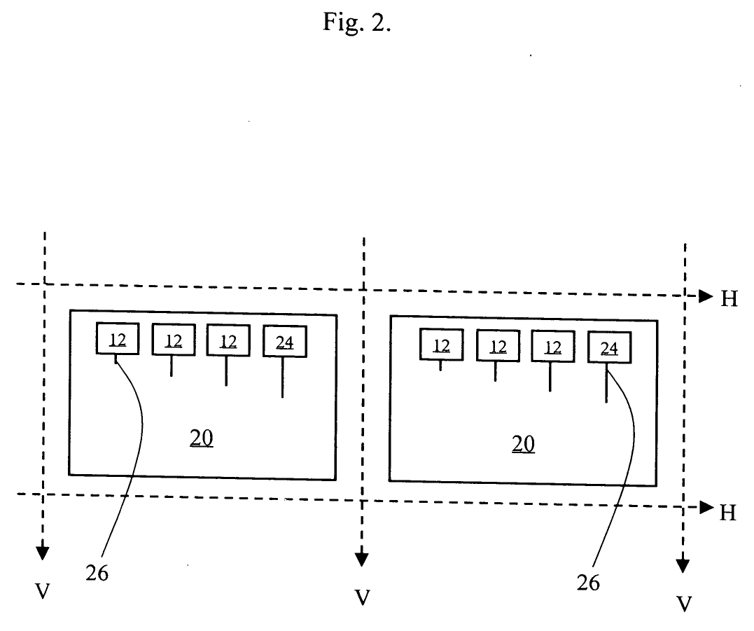

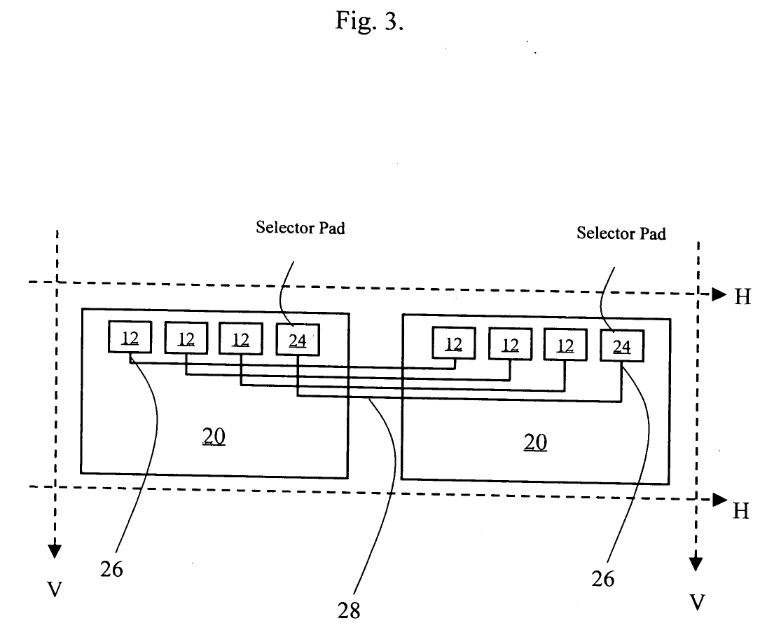

FIG. 2 shows the basic layout of the present invention. A number of substantially the same memory IC areas 20 are laid out on a common wafer. On each memory area 20, there are numerous signal pads 12. A selector pad 24 is laid out on each memory area 20. The selector pad 24 controls a single-pole, double-throw (STDP) switch or 1-bit decoder (not shown), which enables or disables the area on which the selector pad is placed. In manufacturing single capacity memory, dice are fabricated by sawing through the vertical line V2 and the horizontal line H2 in FIG. 2 to yield single capacity memory chips 20. The selector pad 24 presets the STDP or the 1-bit decoder to a fixed logic state (for example, logic “0” state). In order to manufacture double capacity memory ICs product, two neighboring chip areas 20 can be integrated as a unit in wafer stage to provide double memory capacity. As shown in FIG. 3, double capacity memory is fabricated through combining two single capacity memory areas 20. In this case the selector pad 24 directs the system to use the first memory area or the second memory area according to the signal either 0 or 1 to be received. There are two sets of like pads on the integrated product of double capacity memory areas. One set of pads is on the first memory area, and the second set of like pads is on the second memory area. For an end user, only one set of the pads is used to couple to external circuits and another one set of the pads keeps open.

For the integrated products as disclosed in the invention as shown in FIG. 3, all the pads are extended with vertical metal wires 26 with increasing lengths from the left pad toward the right pad as an example. FIG. 3 shows the corresponding pads on different memory area interconnected with horizontal metal wires 28 which can be made through two additional mask layers in addition to the original mask layers for manufacturing products with single capacity as shown in FIG. 2. The first additional mask process is used for making via holes to contact the wires 26 from metal wire 28 on a top layer, and the second mask process is used for producing metal wires 28 on the top layer. Metal wires 28 is connected with wires 26 through the via contacts, for coupling the two sets of corresponding pads on the two memory areas 20.

These two additional mask layers are also used to preset embedded decoder state, and to operate with signal of pad 24. For example, if the signal is 0 received at pad 24, the decoder directs the system to use the left memory area, and if the signal is 1 received at pad 24, the decoder directs the system to use the right memory area. With the aid of the selector pad 24 to control the memory unit on the two memory areas 20, the two memory areas 20 can be unified as a single unit having double memory capacity. After the connection of metal wires 28, the wafer can be sawed along the horizontal scribe lines H3, and the vertical scribe lines V3 as shown in FIG. 3 to yield a double capacity memory IC that is a product combining two like memory areas 20 as a unit die. Since the vertical scribe lines are spaced two memory areas 20 apart, each die has two like memory areas 20 and therefore doubles the memory capacity.

In a similar manner, more than double the memory capacity can be obtained by connecting more than two like memory areas in parallel through additional mask layers, and additional selector pads, in addition to the mask layers for manufacturing a basic memory area.

While the embodiments of the invention have been described, it will be apparent to those skilled in the art that various modifications can be made to the embodiments without departing from the spirit of this invention. Such modifications are all within the scope of this invention.

1. An expandable memory IC, comprising:
two neighboring memory areas on a chip;
a selector pad on each said memory area for enabling said two memory areas; and
interconnections on the chip connecting corresponding pads of said two memory areas to increase memory capacity.

2. The expandable memory as described in claim 1, wherein there are two like memory areas in a single die to double the memory capacity.
